(19) United States
(12) Patent Application Publication
(10) Pub. No.: US 2009/0302302 A1
(43) Pub. Date: Dec. 10, 2009

(54) METAL OXIDE RESISTIVE MEMORY AND METHOD OF FABRICATING THE SAME

(75) Inventors: Jang-Eun HEO, Seoul (KR); Moon-Sook LEE, Seoul (KR); Young-Moon CHOI, Seoul (KR); In-Gyu BAEK, Seoul (KR); Yoon-Ho SON, Gyeonggi-do (KR); Suk-Hun CHOI, Gyeonggi-do (KR); Kyung-Rae BYUN, Gyeonggi-do (KR)

Correspondence Address: MYERS BIGEL SIBLEY & SAJOVEC, PO BOX 37428, RALEIGH, NC, 27627, US

(73) Assignee: SAMSUNG ELECTRONICS CO., LTD., Gyeonggi-Do (KR)

(21) Appl. No.: 12/533,793

(22) Filed: Jul. 31, 2009

Related U.S. Application Data
(62) Division of application No. 11/419,986, filed on May 23, 2006.

(30) Foreign Application Priority Data
May 23, 2005 (KR) 2005-0043124

(51) Int. Cl. H01L 45/00; H01L 21/20

(52) U.S. Cl. 257/4; 438/104; 257/E45.003; 257/E21.09

(57) ABSTRACT

Disclosed is a metal-metal oxide resistive memory device including a lower conductive layer pattern disposed in a substrate. An insulation layer is formed over the substrate, including a contact hole to partially expose the upper surface of the lower conductive layer pattern. The contact hole is filled with a carbon nanotube grown from the lower conductive layer pattern. An upper electrode and a transition-metal oxide layer made of a 2-components material are formed over the carbon nanotube and the insulation layer. The metal-metal oxide resistive memory device is adaptable to high integration and operable with relatively small power consumption by increasing the resistance therein.

### CROSS-REFERENCE TO RELATED PATENT APPLICATION

This application is a Divisional of U.S. Ser. No. 11/419,986, filed on May 23, 2006, now is pending, which claims priority from Korean Patent Application No. 2005-43124 filed on May 23, 2005, all of which are hereby incorporated by reference in their entirety.

### BACKGROUND

The subject matter described herein relates to semiconductor memory devices, and in particular, to a metal oxide resistive memory device and method of fabricating the same.

Semiconductor memory devices are classified into volatile and nonvolatile types in accordance with the ability to preserve data when the supplied power is suspended or cut off. Volatile memory devices include DRAMs and SRAMs, while nonvolatile memory devices include flash memory devices.

Lately, a lot of efforts have been invested in researching next-generation nonvolatile memory devices, such as phase-changeable RAMs, ferroelectric RAMs, and magnetic RAMs.

One of these next-generation devices, the phase-changeable RAM, utilizes properties of material undergoing phase changes, such as comparing the electrical resistance of a crystalline phase with that of an amorphous phase. Here, a data bit “0” can be distinguished from a data bit “1” by assigning one of the values to a particular electrical resistance phase value. In the above example, the electrical resistance may be lower in the crystalline phase than in the amorphous phase, and phases may be altered by joule heating with pulse currents. The phase-changeable RAM is embeddable in a silicon substrate by means of a relatively simple process employing a ternary chalcogenide organized with Ge, Sb, and Te.

Ferroelectric RAM requires the use a compound containing a ternary compound such as PZT, while the magnetic RAM utilizes a complicated multi-level layer containing NiFe or NiFeCo. As these conventional next-generation nonvolatile memory devices require the use of ternary compounds or the formation of multi-level material layers, they are subject to possible deterioration or degradation of the material needed to derive the device characteristics during chemical or heat treatment processes performed during the manufacture of the device. In, addition, the manufacturing process itself is quite complicated and involves substantial resources to complete.

Further, in order to reduce the rate of power consumption, the area of the top or bottom electrode in contact with the phase changeable or ferroelectric material needs to be minimized. To accomplish this, the area of a contact plug electrode should be reduced as much as possible. Generally, in conventional semiconductor memory devices, metal interconnections made of polysilicon or copper are used. A line width of a metal interconnection is generally limited to about 70 nm, which is less than 10⁷ A/cm² for maximum current densities. Since the maximum current densities of nitrides that are widely used as contact plug materials, such as TiN, TiAlN, and so on, are not over than 10⁸ A/cm², those materials are inapplicable for use as contact plugs having relatively small diameters of several nanometers through several tens of nanometers. Furthermore, it is difficult for those materials to fill up contact plug holes with relatively small diameters.

### SUMMARY

In the present invention, nonvolatile memory devices employing transition metal oxides are considered. The transition metal oxides may be two-component metal compounds such as NiO, TiO₂, ZrO₂, HfO₂, Nb₂O₅, CoO₂, CrO₂, and so forth. The nonvolatile memory devices with transition metal oxides may be manufactured by relatively simple processing steps and may be able to endure more thermal and chemical stresses, as compared to the conventional next-generation nonvolatile memory devices. In addition, the nonvolatile memory devices with transition metal oxides can be used with a variety of memory cells and top/bottom electrodes regardless of the dimensions, thus making them suitable for high-density integration.

Also considered in the present invention is the use of carbon nanotubes as contact plugs in semiconductor devices. By employing carbon nanotubes for contact plugs connected to top and/or bottom electrodes in the metal oxide resistive memory device, it is possible to reduce the areas of the top and/or bottom electrodes near the contact plug.

The carbon nanotube may have a maximum current density of about 10⁹ A/cm², and may be able to grow several nanometers in size, making it applicable to contact plugs with diameters less than those formed with TiN or TiAlN. By using carbon nanotubes as contact plugs, it is possible for the metal oxide resistive memory device to have top and bottom electrodes that are under several tens nanometers in size. Thus, in addition to high-density integration, embodiments of the present invention may be advantageous in reducing power consumption.

Embodiments of the present invention thus provide low power metal oxide resistive memory devices capable of high integration, and methods of fabricating the same. According to an embodiment of the present invention, a metal oxide resistive memory device includes a lower conductive layer over the substrate an insulation layer formed over the lower conductive layer, which has a contact hole partially exposing the lower conductive layer, and a carbon nanotube that fills up the contact hole over the lower conductive layer. The device also includes a transition-metal oxide layer that overlaps the carbon nanotube over the insulation layer and a top electrode disposed over the transition-metal oxide layer layer. The metal oxide resistive memory device utilizes the carbon nanotube as a contact plug electrode, having a data storage region constructed with the transition-metal oxide layer and the top electrode formed over the carbon nanotube. The lower conductive layer may further include a catalytic agent for growth of the carbon nanotube.

### BRIEF DESCRIPTION OF THE FIGURES

The accompanying drawings are included to provide a further understanding of the invention, and are incorporated in and constitute a part of this specification. The drawings illustrate example embodiments of the present invention and, together with the description, serve to explain principles of the present invention. In the figures:

FIG. 1 is a graphic view plotting an operational characteristic of a metal oxide resistive memory device using NiO;

FIG. 2 is a cross-sectional view schematically illustrating a metal oxide resistive memory device in accordance with an embodiment of the present invention;

FIGS. 3A through 3C are cross-sectional views schematically illustrating metal oxide resistive memory devices in accordance with other embodiments of the present invention;

FIG. 4 is a cross-sectional view schematically illustrating a metal oxide resistive memory device in accordance with another embodiment of the present invention;

FIG. 5 is a cross-sectional view schematically illustrating a metal oxide resistive memory device in accordance with yet another embodiment of the present invention;

FIG. 6 is a cross-sectional view schematically illustrating a metal oxide resistive memory device in accordance with still another embodiment of the present invention;

FIGS. 7A through 7D are cross-sectional views showing a procedure of fabricating the metal oxide resistive memory device shown in FIG. 2;

FIGS. 8A and 8B are cross-sectional views showing a procedure of fabricating the metal oxide resistive memory device shown in FIG. 3A;

FIGS. 9A and 9B are cross-sectional views showing a procedure of fabricating the metal oxide resistive memory device shown in FIG. 3B;

FIGS. 10A and 10B are cross-sectional views showing a procedure of fabricating the metal oxide resistive memory device shown in FIG. 3C;

FIGS. 11A and 11B are cross-sectional views showing a procedure of fabricating the metal oxide resistive memory device shown in FIG. 4;

FIGS. 12A and 12C are cross-sectional views showing a procedure of fabricating the metal oxide resistive memory device shown in FIG. 5; and

FIGS. 13A and 13B are cross-sectional views showing a procedure of fabricating the metal oxide resistive memory device shown in FIG. 6.

### DETAILED DESCRIPTION

Preferred embodiments of the present invention will be described below in more detail with reference to the accompanying drawings. The present invention may, however, be embodied in many different forms and should not be constructed as limited to the embodiments set forth herein. Rather, these embodiments are provided so that this disclosure will be thorough and complete, and will fully convey the scope of the present invention to those skilled in the art.

In the drawings, the thickness of layers and regions are exaggerated for clarity, and the drawings may not be to scale. It will also be understood that when a layer is referred to as being “on” another layer or substrate, it can be directly on the other layer or substrate, or intervening layers may also be present. Like numerals refer to like elements throughout the specification. Hereinafter, exemplary embodiments of the present invention will be described in conjunction with the accompanying drawings.

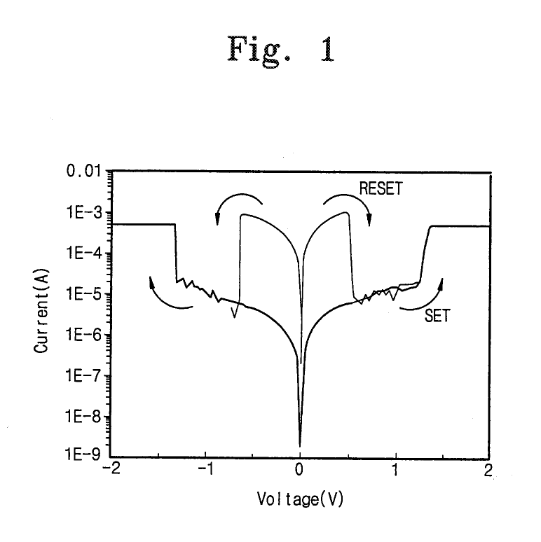

FIG. 1 is a graphic view plotting an operational characteristic of a metal oxide resistive memory device using NiO. The graph shown in FIG. 1 results from evaluating resistance values by applying voltages to top and bottom electrodes formed respectively on upper and lower faces of the NiO layers. In high resistance instances, a voltage about 1.5V applied to the top and bottom electrodes causes the resistance value to be lowered, which is referred to as a SET state. In the SET state (i.e., the low resistive state), a relatively low voltage of less than about 0.5V applied thereto keeps the device in a low resistive state, but a relatively high voltage over about 0.5V turns the current state into the high resistive state that is referred to as RESET state. As such, the resistance value of the device is variable in the range of hundred times in accordance with a voltage applied thereto and maintained on the current state (SET or RESET) even without voltage supply, by which a data bit “0” or “1” is determined each by the SET or RESET state.

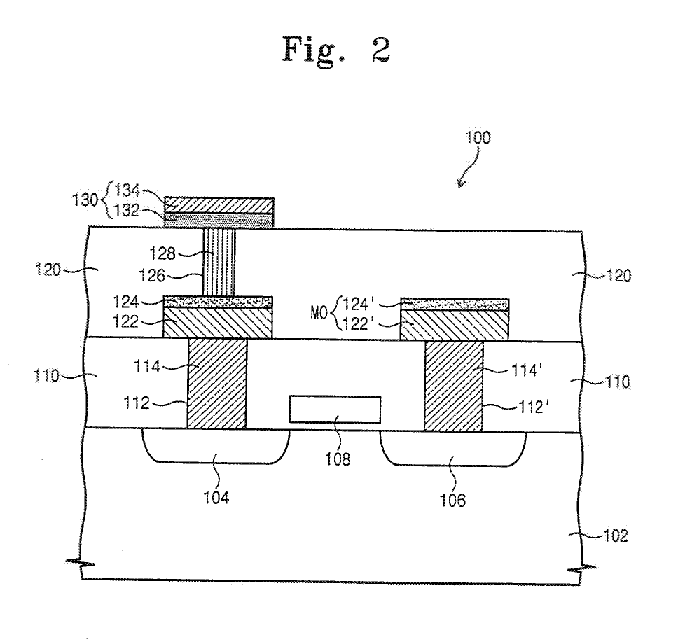

FIG. 2 is a cross-sectional view schematically illustrating a metal oxide resistive memory device 100 in accordance with an embodiment of the present invention. Referring to FIG. 2, a MOSFET is completed by forming source and drain regions 104 and 106 in a substrate 102, and a gate electrode 108 isolated from the source and drain regions through an insulation layer. On this structure of the substrate, a first insulation layer 110 is formed to include first contact holes 112 and 112′ that expose the source and drain regions 104 and 106. Conductive plugs 114 and 114′, formed of, for example, tungsten, fill up the first contact holes 112 and 112′.

On the first insulation layer 110, lower conductive layers 122 and 122′ are arranged to be connected to the tungsten plugs 114 and 114′. On the lower conductive layers 122 and 122′, catalytic layers, 124 and 124′, are staked for growth of the carbon nanotube. The catalytic agents, 124 and 124′, may include a metal chosen from Ni, Al, Co, Mo, Pt, Ca, Cr, Ti, Fe, Zr, W, Ir, Y, WSi, CoSi, NiSi, TiSi, TiW, and so on. The catalytic agents, 124 and 124′ may include an oxide of these metals, or a composite of a plurality of the above materials. The catalytic agents, 124 and 124′, may be substituted with porous active layers generated by an NH₃ plasma process on the lower conductive layers 122 and 122′, and is therefore not restricted to the catalytic metals.

Over the lower conductive layer 122 with the catalytic agent 124, a second insulation layer 120 is formed to include a second contact hole 126 to expose the catalytic agent 124. The second contact hole 126 is filled with a carbon nanotube 128. On the second insulation layer 120 and the carbon nanotube 128, a transition-metal oxide layer 132 is formed to be electrically connected to the carbon nanotube 128. The transition-metal oxide layer is doped with at least one element, such as Li, Cr, Ca, or La. On the transition-metal oxide layer 132, a top electrode 134 is disposed to complete a data storage region therein. The top electrode 134 includes a metal chosen from Ni, Al, Co, Mo, Pt, Fe, Zr, Cr, Ca, Ti, Y, Ir, La, W, Nb, Hf, Cu, and so on. The top electrode 134 may include an oxide of these metals, or includes a composite having a plurality of the above materials.

Here, the lower conductive layer 122′ and the catalytic agent 124′ constitute a metal interconnection MO that is connected to a bitline (not shown).

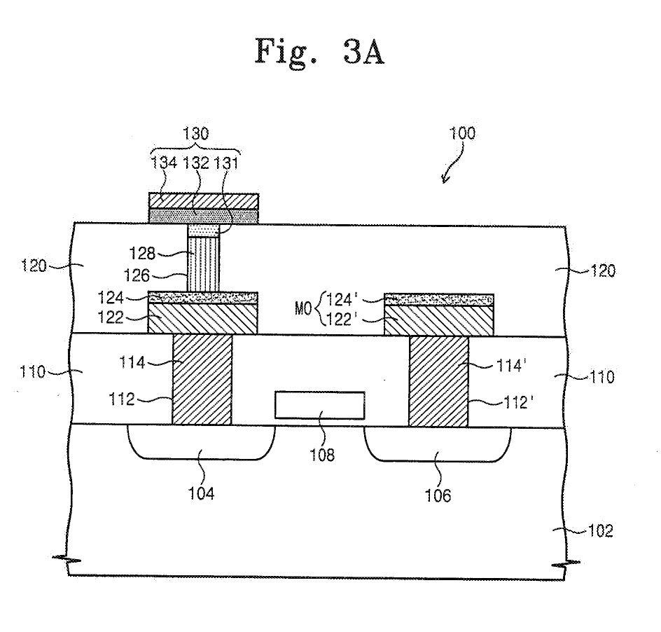

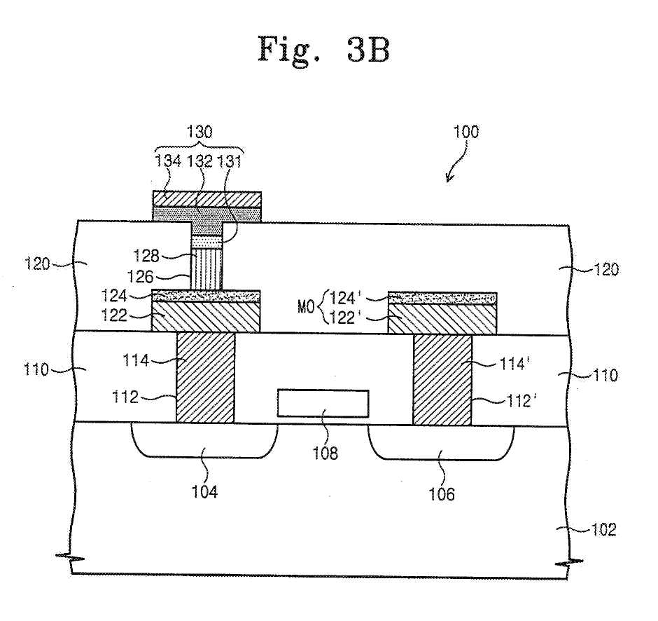

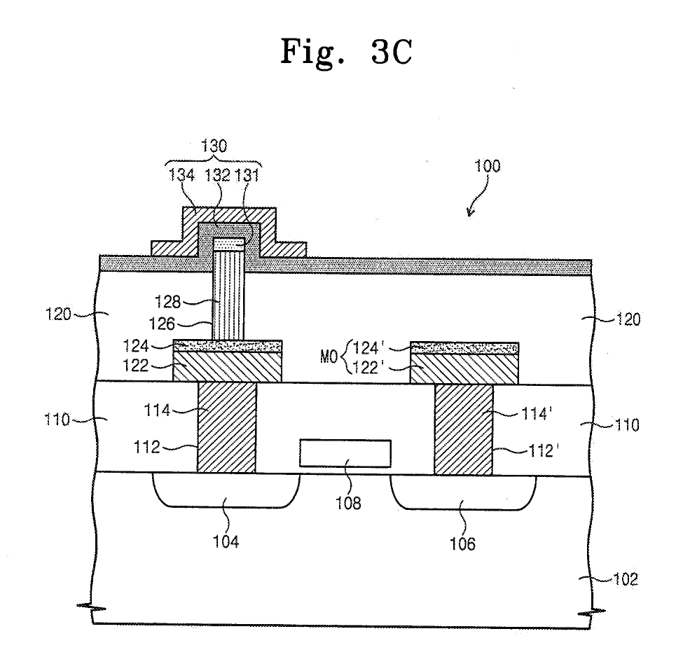

FIGS. 3A through 3C are cross-sectional views schematically illustrating modifications of the metal oxide resistive memory device 100 in accordance with other embodiments of the present invention. Referring to FIG. 3A, the metal oxide resistive memory device 100 includes a bottom electrode 131 disposed under the transition-metal oxide layer 132 so as to improve contact resistance and operation characteristic, which completes the data storage region 130. The bottom electrode 131 may include a metal chosen from Ni, Al, Co, Mo, Pt, Fe, Zr, Cr, Ca, Ti, Y, Ir, La, TiN, TiAlN, and so on. The bottom electrode 131 may include an oxide of these metals, or a composite having a plurality of the above materials. Meanwhile, referring to FIGS. 3B and 3 C, the top face of the bottom electrode 131 may be recessed such that its top surface is lower than the surface of the insulation layer 120, or alternatively may protrude above the surface of the insulation layer 120.

The carbon nanotube 128 is oxidized to induce a degradation of the device characteristics due to the reaction with oxygen from the transition-metal oxide layer 132. The bottom electrode 131 may function as an oxygen diffusion protecting layer when it is made of a nitride such as TiN, TiAlN, TaN, or TaAlN, Ir, or Ru.

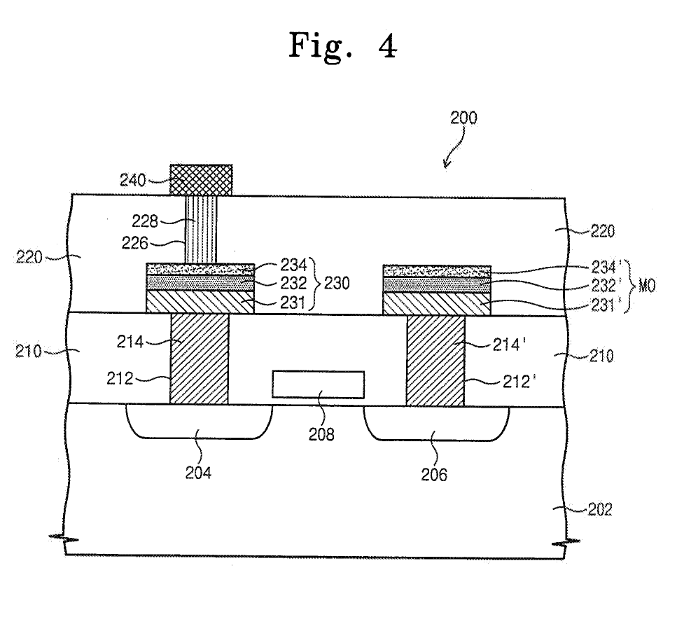

FIG. 4 is a cross-sectional view schematically illustrating a metal oxide resistive memory device 200 in accordance with another embodiment of the present invention. Referring to FIG. 4, the device 200 is comprised of a first insulation layer 210 on the MOSFET structure having source/drain regions, 204 and 206, and a gate electrode 208 in a substrate 202, including first contact holes 212 and 212′. The first contact holes, 212 and 212′, are filled with conductive plugs 214 and 214′ that may include tungsten. On the first insulation layer 210, lower conductive layers, 231 and 231′ and transition-metal oxide layers 232 and 232′ are formed to be connected to the tungsten plugs 213 and 214′. The transition-metal oxide layer may be doped with at least an element such as Li, Cr, Ca, or La. On the transition-metal oxide layers 232 and 232′, catalytic metal layers 234 and 234′ may be formed to help facilitate the growth of the carbon nanotubes. The catalytic agents, 234 and 234′, may include a metal chosen from Ni, Al, Co, Mo, Pt, Ca, Cr, Ti, Fe, Zr, W, Ir, Y, WSi, CoSi, NiSi, TiSi, TiW, and so on. The catalytic agents 234 and 234′ may include an oxide of these metals, or a composite having a plurality of the above materials. Here, the catalytic metal layers may function as top electrodes of the transition-metal oxide layer 232 and 232′. Thus, the lower conductive layers 231 and 231′, the transition-metal oxide layer 232 and 232′, and the catalytic metal layers 234 and 234′ constitute a data storage region 230 and a metal interconnection MO. The catalytic agent may be the porous active layer.

A second insulation layer 220 is formed with covering the catalytic agents 234 and 234′, including a second contact hole 226. The second contact hole 226 is filled with a carbon nanotube 228. A metal interconnection layer 240 is formed on the upward faces of the carbon nanotube 229 and the second insulation layer 220, being electrically connected with the carbon nanotube 229.

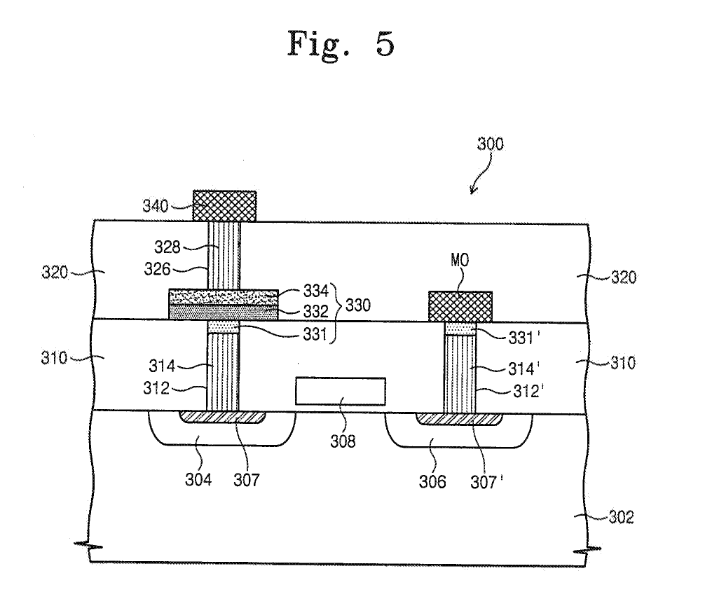

FIG. 5 is a cross-sectional view schematically illustrating a metal oxide resistive memory device 300 in accordance with yet another embodiment of the present invention. Referring to FIG. 5, silicide layers 307 and 307′ are formed in predetermined positions in the source/drain regions 304 and 306 on the substrate 302, being formed by way of a typical processing method with a silicide material such as CoSi, TiSi, WSi, or NiSi. On the resultant structure of the substrate, a first insulation layer 310 is formed to include first contact holes, 312 and 312′, which expose the silicide layers 307 an 307′. Carbon nanotubes, 314 and 314′, grow up through catalysis reactions from each of the silicide layers 307 and 307′ to fill the first contact holes 312 and 312′.

Bottom electrodes 331 and 331′ are formed on the carbon nanotubes 314 and 314′. The bottom electrodes 331 and 331′ may include a metal chosen from Ni, Nb, Ti, Zr, Hf, Co, Fe, Cu, Al, Cr, TiN, TiAlN, and so on. The bottom electrodes 331 and 331′ may include a composite having a plurality of the above materials. The carbon nanotube is oxidized to induce a degradation of the device characteristics, due to the reaction with oxygen from a transition-metal oxide layer 332. The bottom electrode 331 may function as an oxygen diffusion protecting layer when it is made of a nitride, such as TiN, TiAlN, TaN, TaAlN, Ir, or Ru.

The transition-metal oxide layer 332 and a catalytic agent 334 are stacked on the first insulation layer 310 and the bottom electrode 331 in sequence. The transition-metal oxide layer is doped with at least an element, such as Li, Cr, Ca, or La. The catalytic agent 334 may include a metal chosen from Ni, Al, Co, Mo, Pt, Ca, Cr, Ti, Fe, Zr, W, Ir, Y, WSi, CoSi, NiSi, TiSi, TiW, and so on. The catalytic agent 334 may include an oxide of these metals, or a composite having a plurality of the above materials. The catalytic metal layer 334 may function as the top electrode of the transition-metal oxide layer 332. Thus, the bottom electrode 331, the transition-metal oxide layer 332, and the catalytic metal layer 334 constitute a data storage region 330.

A second insulation layer 320 including a second contact hole 326 is formed to cover the catalytic agent 334. The second contact hole 326 is filled with a carbon nanotube 328 that contacts to the catalytic agent 334. A metallic interconnection layer 340 is formed on the carbon nanotube 328 and the second insulation layer 320 to be electrically connected with the carbon nanotube 328.

Meanwhile, the metal interconnection MO may be disposed on the first insulation layer 310 and the bottom electrode 331′.

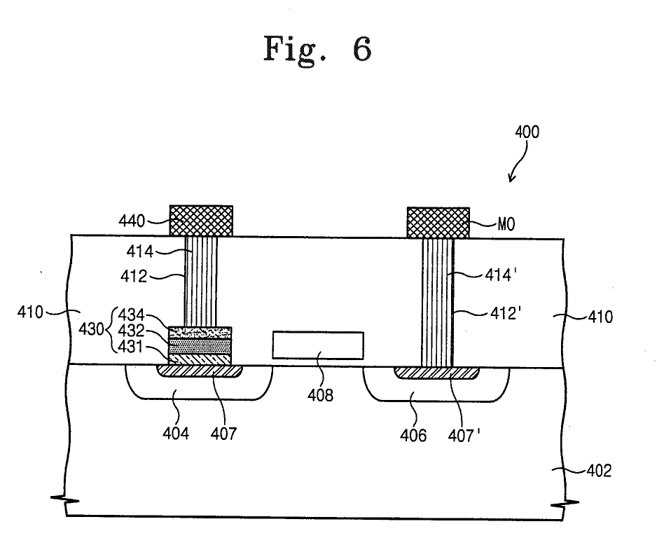

FIG. 6 is a cross-sectional view schematically illustrating a metal oxide resistive memory device 400 in accordance with still another embodiment of the present invention.

Referring to FIG. 6, the metal silicide layers 407 and 407′ are formed in predetermined positions of source/drain regions 404 and 406 in the MOSFET structure including the source/drain regions 404 and 406 and a gate electrode 408. A transition-metal oxide layer 432 is provided on an oxygen diffusion-protecting layer 431, which may include TiN, TiAlN, TaN, or TaAlN, on the metal silicide layer 407, where the transition-metal oxide layer 432 is electrically connected to the source region 404. The oxygen diffusion-protecting layer 431 is interposed between the transition-metal oxide layer 432 and the metal silicide layer 407. The oxygen diffusion-protecting layer 431 is provided to prevent the source region 404 from being oxidized by the transition-metal oxide layer 432, which may generate contact failures therein. The diffusion-protecting layer 431 may function as the bottom electrode of the transition-metal oxide layer 432. A catalytic metal layer 434 is stacked on the transition-metal oxide layer 432 to help facilitate the growth of the carbon nanotubes. The catalytic agent 434 may include a metal chosen from Ni, Al, Co, Mo, Pt, Ca, Cr, Ti, Fe, Zr, W, Ir, Y, WSi, CoSi, NiSi, TiSi, TiW, and so on. The catalytic agent 434 may include an oxide of these metals, or a composite having a plurality of the above materials. The catalytic metal layer 434 may function as the top electrode of the transition-metal oxide layer 432. Thus, the bottom electrode 431, the transition-metal oxide layer 432, and the catalytic metal layers 434 may constitute a data storage region 430. The catalytic agent may be the porous active layer.

An insulation layer 410 including contact holes 412 and 412′ is formed to cover the catalytic agent 434 and the silicide layer 407′. The contact holes 412 and 412′ are filled with carbon nanotubes 414 and 414′. Metallic interconnection layers, 440 and MO, are formed on the carbon nanotubes 414 and 414′ and the insulation layer 410 to be electrically connected with the respective carbon nanotubes 414 and 414′.

The lower conductive layer, i.e., the bottom electrode 431, includes at least one among W, Ti, Mo, Ta, TiSi, polysilicon, TiN, WN, MoN, NbN, TiSiN, TiAlN, TiBN, ZrSiN, WSiN, WSiN, WBN, ZrAlN, MoSiN, MoAln, TaSiN, TaAlN, TiON, TiAlON, WON, TaON, Pt, Ru, Ir, Os, and Pd, or includes a composite having a plurality of the above materials. The transition-metal oxide layer 432 includes at least one oxide among NiO, TiO₂, ZrO₂, HfO₂, Nb₂O₅, CoO₂, and CrO₂. The transition-metal oxide layer 432 may further be doped with at least an element such as Li, Cr, Ca, or La.

Whereas the aforementioned embodiments are described and illustrated with the carbon nanotubes being formed by growth from a catalytic metal layer that is stacked on the transition-metal oxide layer, the present invention is not limited to these embodiments. Rather, for instance, the carbon nanotubes may be grown using the transition-metal oxide layer without the catalytic agent, because the transition-metal oxide layer itself functions as a catalyst for the growth of the carbon nanotubes. Accordingly, embodiments of the present invention may not require any process of forming the catalytic agent, as a catalyst may be available to complete the transition-metal oxide layer and the carbon nanotube by way of simple processing steps carried out in sequence. Otherwise, the carbon nanotube may be grown from the porous active layers generated by an NH₃ plasma process on conductive layers.

Now, embodiments of processing methods for fabricating the metal oxide resistive memory devices in accordance with the present invention will be described. Hereafter, the catalytic metal layer will be described as the catalytic agent.

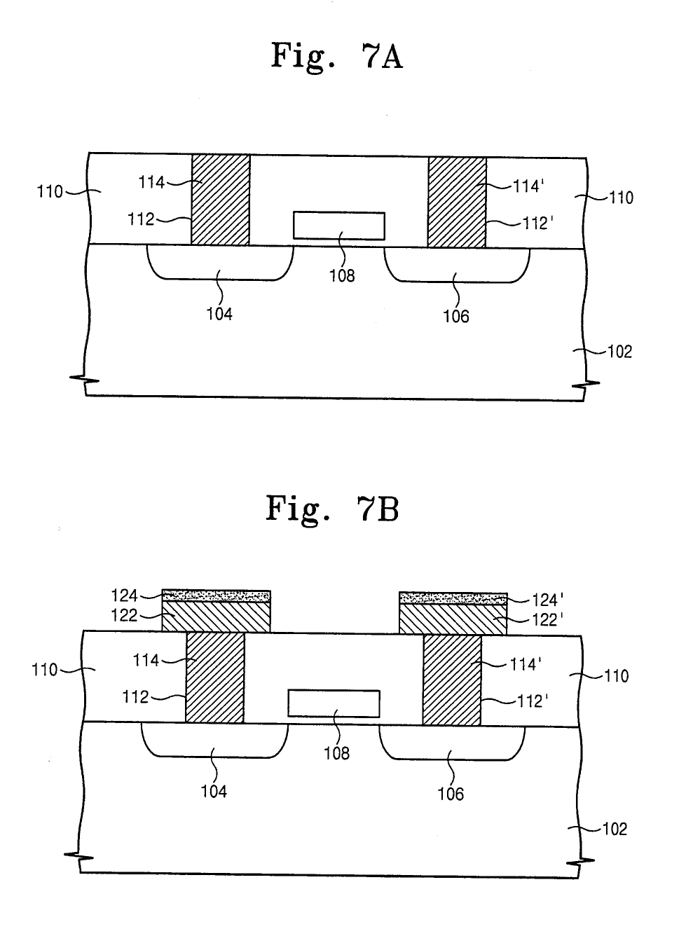

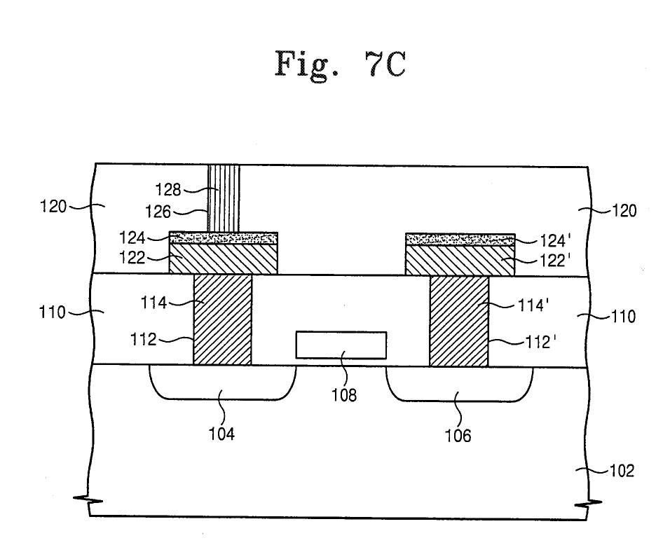

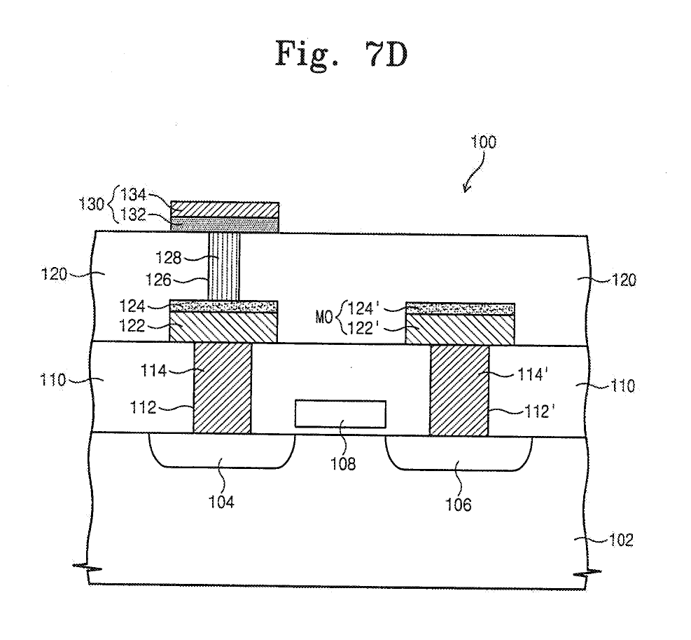

FIGS. 7A through 7D are cross-sectional views showing a procedure of fabricating the metal oxide resistive memory device 100 shown in FIG. 2.

First referring to FIG. 7A, active fields for MOSFET structures are separately defined by field isolation layers (not shown) on a cell array of the substrate 102. In the active region, the MOSFET structure is completed by forming the source and drain regions 104 and 106, and the gate electrode 108 isolated from the source and drain regions through a gate insulation layer (not shown). The first insulation layer 110 is deposited on the structure of the substrate. Then the first contact holes 112 and 112′ are formed in the first insulation layer 110 to expose the source and drain regions 104 and 106. The first contact holes 112 and 112′ are filled with a conductive material, such as tungsten (W) and flattened to form the tungsten plugs 114 and 114′.

Referring to FIG. 7B, the lower conductive layers 122 and 122′ are deposited on the first insulation layer 110 to be connected to the tungsten plugs 114 and 114′. The lower conductive layers 122 and 122′ may include at least one among W, Ti, Mo, Ta, TiSi, polysilicon, TiN, WN, MoN, NbN, TiSiN, TiAlN, TiBN, ZrSiN, WSiN, WSiN, WBN, ZrAlN, MoSiN, MoAln, TaSiN, TaAlN, TiON, TiAlON, WON, TaON, Pt, Ru, Ir, Os, and Pd, or include a composite having a plurality of the above materials.

On the lower conductive layers 122 and 122′, the catalytic metal layers 124 and 124′ are stacked and then patterned at the same time. The catalytic layers 124 and 124′ may include at least one among metals such as Ni, Al, Co, Mo, Pt, Ca, Cr, Ti, Fe, Zr, W, Ir, Y, WSi, CoSi, NiSi, TiSi, TiW, and so on, include at least one oxide with the metal, or include a composite having a plurality of the above materials. While carbon nanotubes may typically be grown by means of the catalytic reaction, it should not be restricted to using the catalytic metals. In these cases, the carbon nanotubes will grow from the porous active layers generated by an NH₃ plasma process on the lower conductive layers 122 and 122′,

Next, referring to FIG. 7C, the second insulation layer 120 is deposited to cover the lower conductive layers 122 and 122′ and the catalytic metal layers 124 and 124′. In the second insulation layer 120, the second contact hole 126 is formed to expose the catalytic metal layer 124.

The carbon nanotube 128 may then be grown from the exposed catalytic metal layer 124 disposed on the lower conductive layer 122. The growth of the carbon nanotube 128 may be conducted by a thermal CVD or plasma-enhanced CVD (PECVD), or by other processes known in the art. In thermal CVD, the process is carried out under a temperature of about 400 to about 900° C., where a reaction chamber is supplied with a gas such as C₂H₂, CH₄, CO, CO₂, ethanol, and methanol, or a mixture of these gases, accompanied by a carrier gas such as Ar, N₂, He, and so on. Such carbon-containing gas supplied into the reaction chamber meets with the catalytic metal layer 124 that is exposed through the second contact hole 126. Accordingly, the carbon nanotube 128 may be grown from the catalytic metal layer 124 in a substantially vertical direction, filling the second contact hole 126.

Referring to FIG. 7D, the transition-metal oxide layer 132 may include a two-component material deposited on the second insulation layer 120 and the carbon nanotube 128 to be connected to the carbon nanotube 128. The transition-metal oxide layer 132 contains at least an oxide among NiO, TiO₂, ZrO₂, HfO₂, Nb₂O₅, CoO₂, and CrO₂. The transition-metal oxide layer may be doped with at least an element such as Li, Cr, Ca, or La.

Meanwhile, in the case of growing the carbon nanotube using the catalytic metal, at least a portion of the catalytic metal layer used for the growth may still remain on the carbon nanotube. Therefore, when the catalytic material is a transition metal, the transition-metal oxide layer may be able to be obtained just by oxidizing the catalytic metal without forming the transition-metal oxide layer.

Otherwise, the catalytic metal layer 124 used for growing the carbon nanotube may be removed therefrom before forming the transition-metal oxide layer 132. Removing the catalytic metal layer 124 may be conducted by a full etch-back or CMP (chemical-mechanical polishing) process on the upper portion of the carbon nanotube 128 including the remaining catalytic metal, which results in exposing the carbon nanotube 128. FIGS. 7C and 7D illustrate the features of removing the catalytic metal.

The top electrode 134 is then stacked on the transition-metal oxide layer 132. Thereafter, the transition-metal oxide layer 132 and the top electrode 134 are patterned to completing the data storage region 130. The top electrode 134 includes at least one among Ni, Al, Co, Mo, Pt, Fe, Zr, Cr, Ca, Ti, Y, Ir, La, W, Nb, Hf, Cu, and so on, includes at least one oxide with the metal, or includes a composite having a plurality of the above materials.

After this process, a third insulation layer (not shown) is deposited on the resultant structure, covering the data storage region 130. A third contact hole (not shown) is formed in the third insulation layer. The top electrode 134 of the data storage region 130 is connected to an interconnection layer (not shown) through the third contact hole.

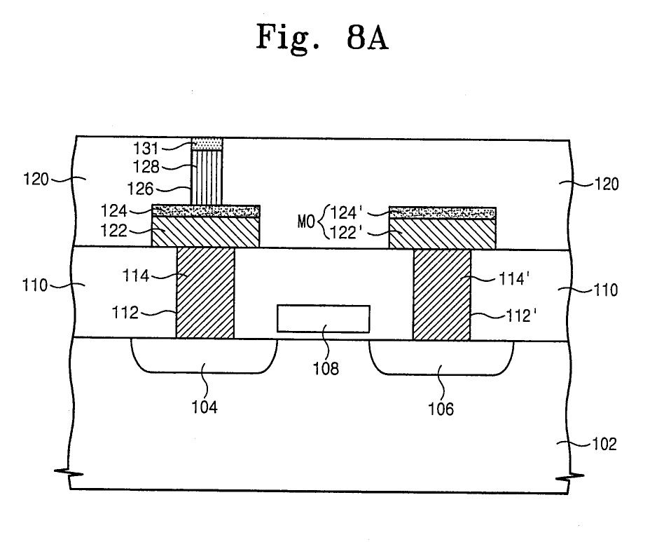

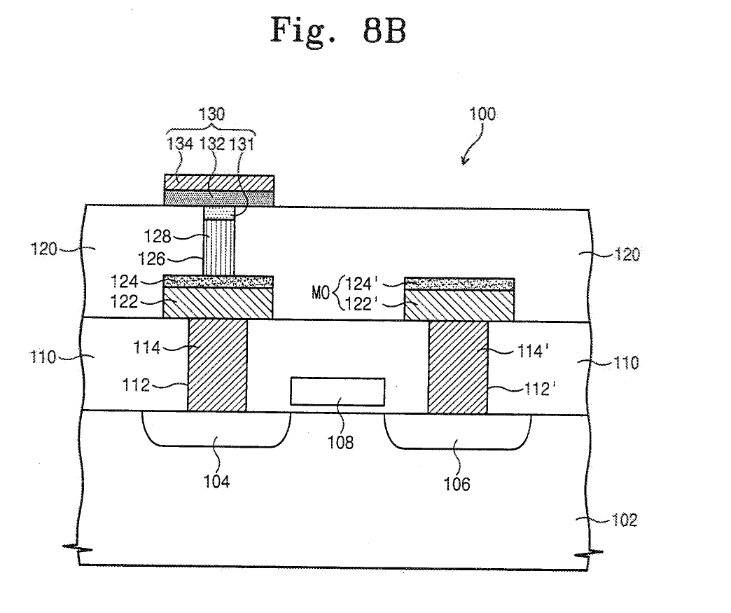

While the data storage region 130 shown in FIG. 7D is illustrated as being formed of the transition-metal oxide layer 132 and the top electrode 134, it is not necessarily limited thereto as described hereinafter within the scope of the present invention. FIGS. 8A through 8B are cross-sectional views showing a procedure of fabricating the metal oxide resistive memory device 100 shown in FIG. 3A.

Referring to FIG. 8A, in order to improve the characteristics of contact resistance and operations, the bottom electrode 131 may be formed on the carbon nanotube 128 as shown in FIG. 7C. Thus, the data storage region 130 is composed of the bottom electrode 131, the transition-metal oxide layer 132, and the top electrode 134. The bottom electrode 131 includes at least one among metals such as Ni, Al, Co, Mo, Pt, Fe, Zr, Cr, Ca, Ti, Y, Ir, La, TiN, TiAlN, and so on, includes at least one oxide with the metal, or includes a composite having a plurality of the above materials.

As opposed to the embodiment shown in FIG. 7C, the carbon nanotube 128 may be formed to have a top surface lower than the surface of the second insulation layer 120. Before forming the bottom electrode 131, the remaining catalytic metal is removed therefrom by conducting the etch-back process partially on the carbon nanotube 128 containing the catalytic metal thus exposing the top portion of the carbon nanotube. Therefore the height of the carbon nanotube 128 may be adjusted by controlling a growing time thereof or regulating the etching-back amount after forming the carbon nanotube 128.

Meanwhile, the bottom electrode 131 is formed to be so that the top surface of the bottom electrode 131 is on the same level with the surface of the second insulation layer 120. For this, the bottom electrode 131 is deposited to fill the second contact hole 126, and then shaved down by way of the full etch-back or CMP process.

The carbon nanotube 128 is oxidized to induce a degradation of the device characteristics by reacting the carbon nanotube 128 with oxygen from the transition-metal oxide layer 132. The bottom electrode 131 is available to function as an oxygen diffusion protecting layer when it is made of a nitride such as TiN, TiAlN, TaN, or TaAlN, Ir, or Ru

While the description relevant to FIG. 8A states that the remaining catalytic metal used for the growth of the carbon nanotube is removed therefrom before forming the bottom electrode, the remaining catalytic metal on the carbon nanotube may be otherwise used as the bottom electrode.

Subsequently, referring to FIG. 8B, the data storage region 130 is completed by a process similar to that of FIG. 7D. And, as aforementioned, the additional insulation layer and the contact hole are formed over the data storage region 130, in which the data storage region 130 is connected to the interconnection layer through the contact hole.

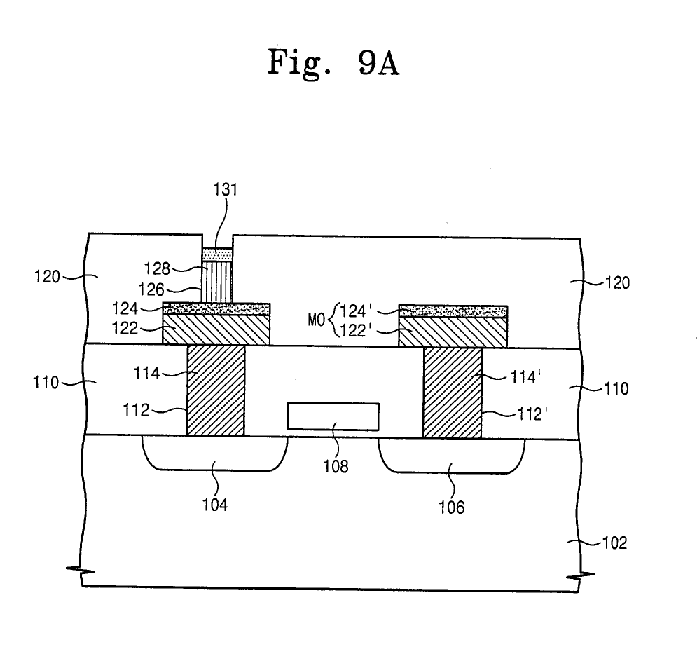

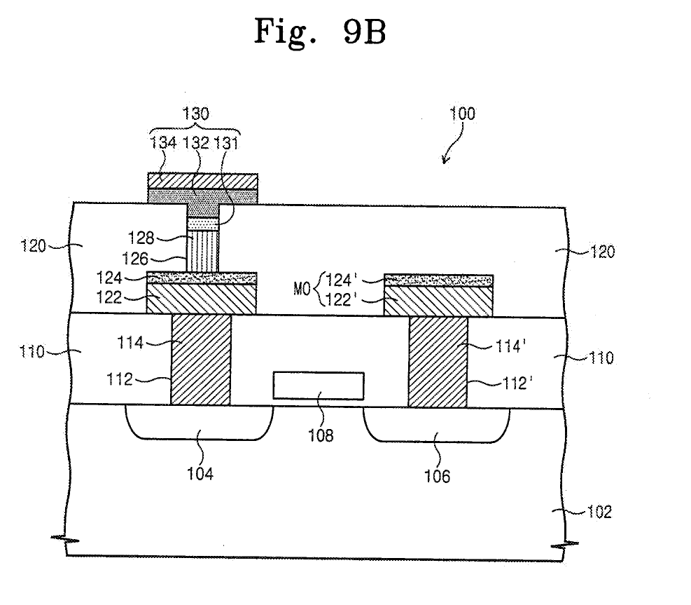

FIGS. 9A through 9B are cross-sectional views showing a procedure of fabricating the metal oxide resistive memory device 100 shown in FIG. 3B.

Whereas the feature of FIG. 8B shows that the bottom electrode 131 on the carbon nanotube 128 is substantially leveled with a surface of the second insulation layer 120 in height, the bottom electrode 131 shown in FIGS. 9A and 9B is formed to be lower than the surface of the second insulation layer 120.

Referring to FIG. 9A, from the step of FIG. 7C, the bottom electrode 131 is formed to be lower than the surface of the second insulation layer 120. The height of the carbon nanotube 128 may be controlled by adjusting the growing time of the carbon nanotube 128 or by adjusting the etch-back rate after forming the carbon nanotube 128. Referring to FIG. 9B, the transition-metal oxide layer 132 and the top electrode 134 are deposited in sequence and then simultaneously patterned to complete the data storage region 130.

While the catalytic metal used for the growth of the carbon nanotube 128 can be removed by way of the etch-back process before depositing the bottom electrode 131, the catalytic metal remaining on the carbon nanotube 128 may be used as the bottom electrode by itself.

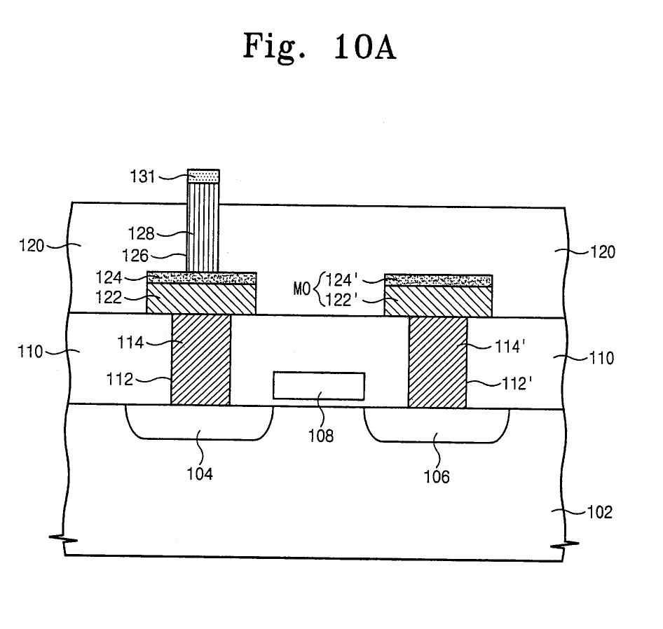

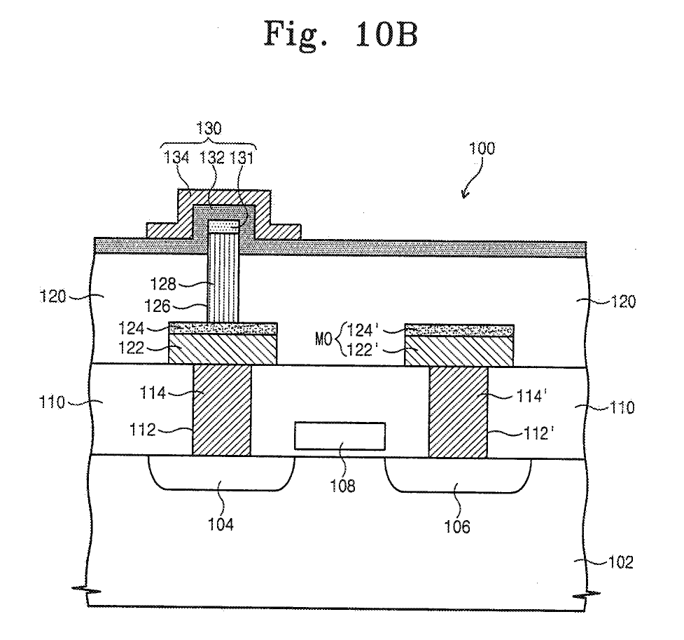

FIGS. 10A through 10B are cross-sectional views showing a procedure of fabricating the metal oxide resistive memory device shown in FIG. 3C.

Referring to FIG. 10A, the bottom electrode 131 is formed to protrude above the surface of the second insulation layer 120. From the processing step of FIG. 7C, the carbon nanotube 128 may be grown until it protrudes over the second insulation layer 120. After depositing an insulation layer, such as an oxide layer, on the protruded carbon nanotube 128 and the second insulation layer 120, an etch-back process is carried out for the overall structure and thereby an insulation spacer (not shown) are formed on the sidewall of the protruded carbon nanotube 128. Next, the bottom electrode 131 is deposited on the carbon nanotube 128. While FIG. 10B illustrates that the bottom electrode 131 is settled on only the carbon nanotube 128, the bottom electrode 131 may be further formed on the second insulation layer 120 in substance. But, the bottom electrode 131 on the second insulation layer 120 is disconnected with the carbon nanotube 128 by the insulation spacer. On the resultant structure thereof, the transition-metal oxide layer 132 and the top electrode 134 are deposited in sequence and then patterned to complete the data storage region 130.

While the catalytic metal used for the growth of the carbon nanotube 128 can be removed by way of the etch-back process before depositing the bottom electrode 131, the catalytic metal remaining on the carbon nanotube 128 may be used as the bottom electrode by itself.

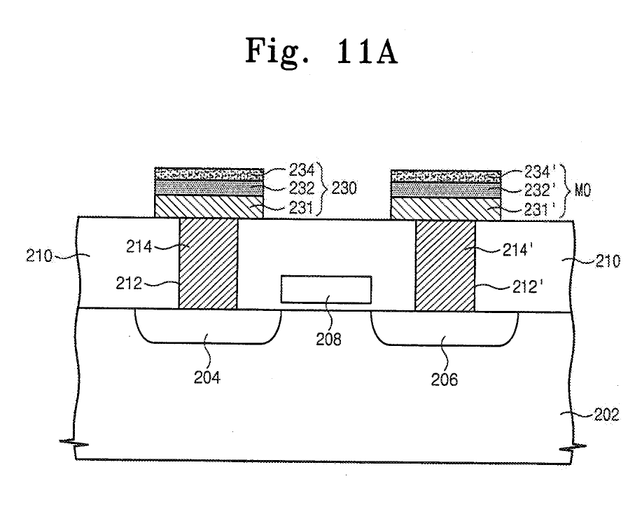

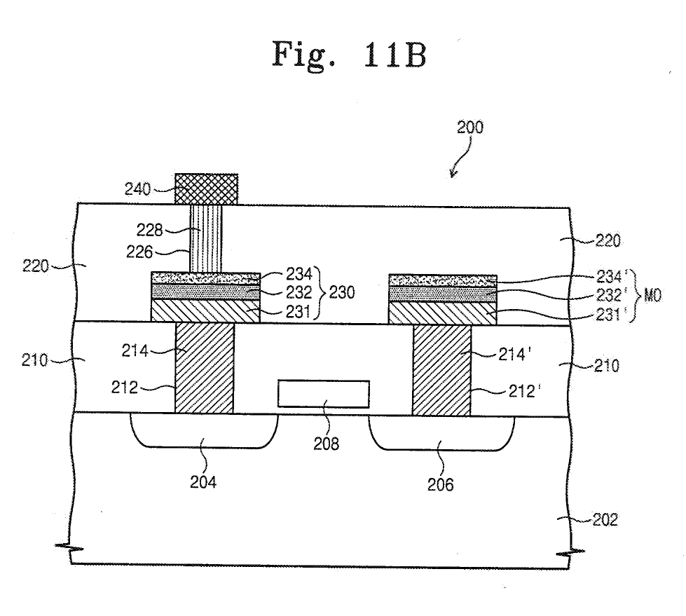

FIGS. 11A through 11B are cross-sectional views showing a procedure of fabricating the metal oxide resistive memory device shown in FIG. 4.

Similar to the processing feature shown in FIG. 7A, after forming the first insulation layer 210 and the first contact holes 212 and 212′, the first contact holes 212 and 212′ are filled with the tungsten plugs 214 and 214′.

Referring to FIG. 11A, on the first insulation layer 210, the lower conductive layers 231 and 231′ are formed to be connected to the tungsten plugs 214 and 214′. The lower conductive layers 231 and 231′ may include at least one among W, Ti, Mo, Ta, TiSi, polysilicon, TiN, WN, MoN, NbN, TiSiN, TiAlN, TiBN, ZrSiN, WSiN, WSiN, WBN, ZrAIN, MoSiN, MoAln, TaSiN, TaAlN, TiON, TiAlON, WON, TaON, Pt, Ru, Ir, Os, and Pd, or include a composite having a plurality of the above materials.

The transition-metal oxide layers 232 and 232′ are formed on the lower conductive layers 231 and 231′. The transition-metal oxide layers may contain at least an oxide among NiO, TiO₂, ZrO₂, HfO₂, Nb₂O₅, CoO₂, and CrO₂. The transition-metal oxide layer may further be doped with at least an element such as Li, Cr, Ca, or La.

Next, the catalytic metal layers 234 and 234′ are formed on the transition-metal oxide layer layers 232 and 232′ to facilitate the growth of the carbon nanotube. The catalytic metal layers 234 and 234′ may include at least one among metals such as Ni, Al, Co, Mo, Pt, Ca, Cr, Ti, Fe, Zr, W, Ir, Y, WSi, CoSi, NiSi, TiSi, TiW, and so on, include at least one oxide with the metal, or include a composite having a plurality of the above materials. Here, the catalytic metal layers 234 and 234′ function as top electrodes of the transition-metal oxide layer 232 and 232′.

Subsequently, the lower conductive layers 231 and 231′, the transition-metal oxide layer 232 and 232′, and the catalytic metal layers 234 and 234′ are patterned together to complete the data storage region 230 and the metal interconnection MO.

Referring to FIG. 11B, the second insulation layer 220 is deposited on the overall structure, covering the catalytic metal layers 234 and 234′. The second contact hole 226 is formed in the second insulation layer 220 to expose the catalytic metal layer 234. The carbon nanotube 228 may be grown from the exposed catalytic metal layer 234, to fill the second contact hole 226. A technical method for growing the carbon nanotube is identical with or similar to that of FIG. 7C, and the catalytic metal on the carbon nanotube 228 may subsequently be removed therefrom.

The metal interconnection layer 240 may then be formed on the carbon nanotube 228 and the second insulation layer 220 to be electrically connected with the carbon nanotube 228.

Again, the present invention is not limited to the method of growing the carbon nanotube from the catalytic metal layer formed on the transition-metal oxide layer. Rather, the carbon nanotube may also be grown by using the transition-metal oxide layer as a catalytic agent without the addition of a separate catalytic metal. This is because the transition-metal oxide layer is available as a catalytic agent by itself for the growth of the carbon nanotube. Accordingly, it is possible to simply form the transition-metal oxide layer and the carbon nanotube through successive processing steps even without an additional processing step of forming the catalytic metal.

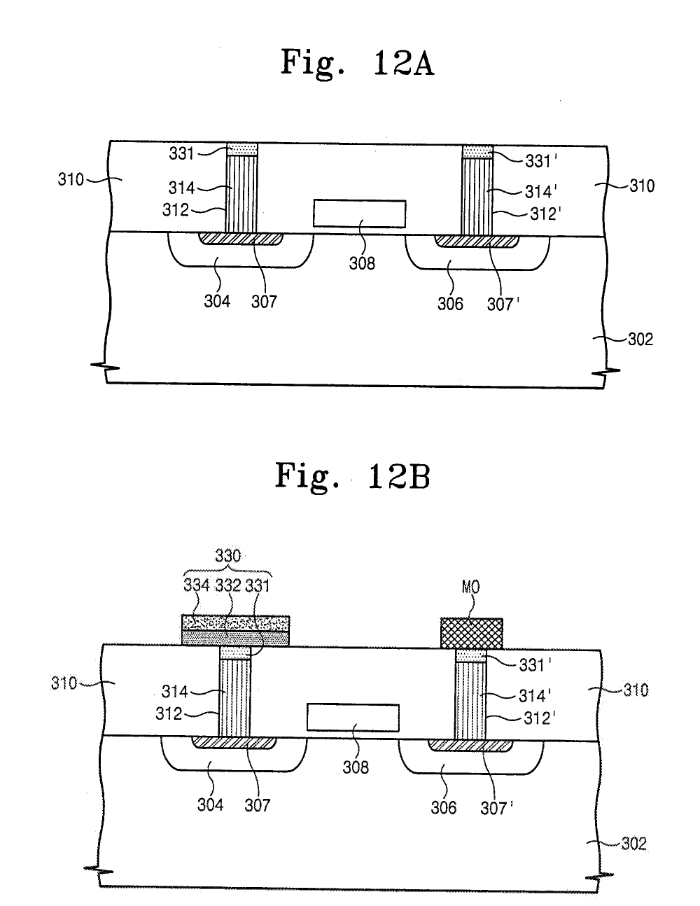

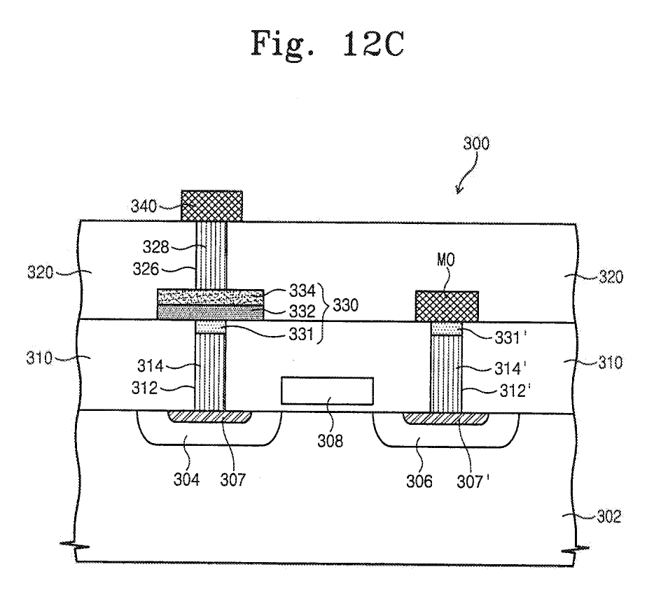

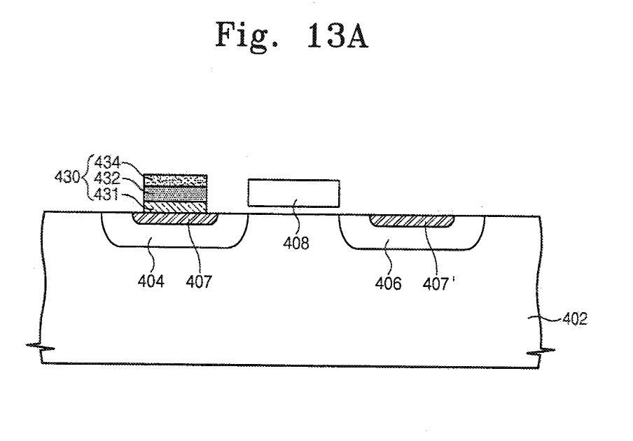

FIGS. 12A through 12C are cross-sectional views showing a procedure of fabricating the metal oxide resistive memory device shown in FIG. 5.

Referring to FIG. 12A, active fields for MOSFET structures are separately defined by field isolation layers (not shown) on a cell array of the substrate 302. In the active region, the MOSFET structure is completed by forming the source and drain regions 304 and 306, and the gate electrode 308 isolated from the source and drain regions through a gate insulation layer. The silicide layers 307 and 307′ are formed in predetermined positions of the source/drain regions 304 and 306 on the substrate 302, being formed by way of a typical processing method with a silicide material such as CoSi, TiSi, WSi, or NiSi.

On the resultant structure of the substrate, the first insulation layer 310 is formed to include first contact holes 312 and 312′ which expose the silicide layers 307 an 307′. The carbon nanotubes 314 and 314′ may be grown through catalysis reactions from the respective silicide layers 307 and 307′, and to fill the first contact holes 312 and 312′. A technical method for growing the carbon nanotube is identical with or similar to that of FIG. 7C, and the catalytic metal silicide on the carbon nanotube 228 may be removed therefrom.

Thereafter, the bottom electrodes 331 and 331′ are formed on the carbon nanotubes 314 and 314′. The bottom electrodes 331 and 331′ may include at least one among metals such as Ni, Nb, Ti, Zr, Hf, Co, Fe, Cu, Al, Cr, TiN, TiAlN, and so on, or include a composite having a plurality of the above materials. The bottom electrodes 331 and 331′ may be leveled with the first insulation layer 310. To accomplish this, after fully filling the first contact holes 312 and 312′ by depositing the bottom electrodes 331 and 331′, an etch-back or CMP process is carried out to shave down the bottom electrodes.

The carbon nanotube is oxidized to induce a degradation of the device characteristics, due to the reaction with oxygen from a transition-metal oxide layer. The bottom electrode 331 may function as an oxygen diffusion protecting layer when it is made of a nitride such as TiN, TiAlN, TaN, TaAlN, Ir, or Ru.

Referring to FIG. 12B, the metal interconnection MO is formed and patterned on the bottom electrode 331′. After depositing an insulation layer (not shown) that only covers the metal interconnection MO, the transition-metal oxide layer 332 may be formed to be connected to the bottom electrode 331. The transition-metal oxide layer 332 contains at least an oxide among NiO, TiO₂, ZrO₂, HfO₂, Nb₂O₅, CoO₂, and CrO₂. Preferably, the transition-metal oxide layer 332 is doped with at least an element such as Li, Cr, Ca, or La.

The catalytic metal layer 334 is formed on the transition-metal oxide layer 332. The catalytic metal layer 334 may include at least one among metals such as Ni, Al, Co, Mo, Pt, Ca, Cr, Ti, Fe, Zr, W, Ir, Y, WSi, CoSi, NiSi, TiSi, TiW, and so on, include at least one oxide with the metal, or include a composite having a plurality of the above materials. The catalytic metal layer 334 may function as the bottom electrode of the transition-metal oxide layer 332. Thus, the bottom electrode 331, the transition-metal oxide layer 332, and the catalytic metal layers 334 may constitute the data storage region 330.

Referring to FIG. 12C, the second insulation layer 320 is deposited to cover the catalytic metal layer 334. The second contact hole 326 is then formed in the second insulation layer 320 to expose the catalytic metal layer 334. The carbon nanotube 328 may then be grown from the catalytic metal layer 334 to fill the second contact hole 326. A technical method for growing the carbon nanotube is identical with or similar to that of FIG. 7C, and the catalytic metal on the carbon nanotube 328 may be removed therefrom.

Subsequently, a metallic interconnection layer 340 is formed on the carbon nanotube 328 and the second insulation layer 320 to be connected with the carbon nanotube 328.

Again, the present invention is not limited to the method of growing the carbon nanotube from the catalytic metal layer formed on the transition-metal oxide layer. Rather, the carbon nanotube may also be grown using the transition-metal oxide layer as a catalytic agent without a separate catalytic metal. This is because the transition-metal oxide layer is available as a catalytic agent by itself for the growth of the carbon nanotube. Accordingly, it is possible to simply form the transition-metal oxide layer and the carbon nanotube through successive processing steps without an additional processing step of forming the catalytic metal.

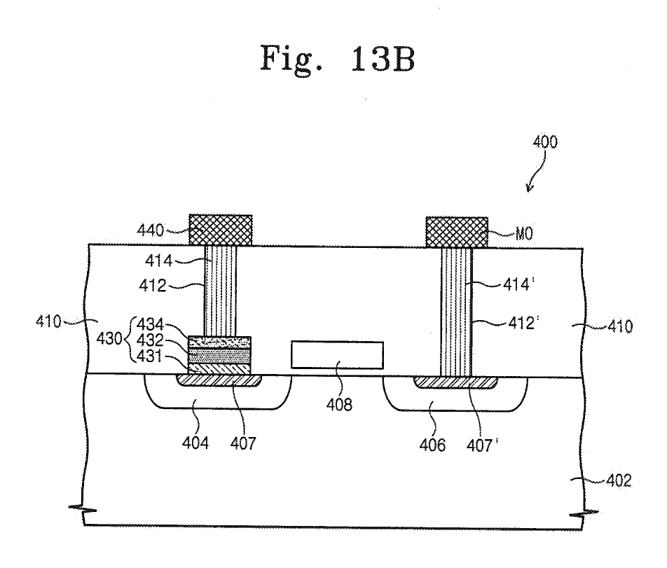

FIGS. 13A and 13B are cross-sectional views showing a procedure of fabricating the metal oxide resistive memory device shown in FIG. 6.

Referring to FIG. 13A, active fields for MOSFET structures are separately defined by field isolation layers (not shown) on a cell array of the substrate 402. In the active region, the MOSFET structure is completed by forming the source and drain regions 404 and 406, and the gate electrode 408 isolated from the source and drain regions through an insulation layer (now shown).

The metal silicide layers 407 and 407′ are formed in portions of source/drain regions 404 and 406 by means of a typical processing technique using a silicide material such as CoSi, TiSi, WSi, or NiSi. After depositing an insulation layer (not shown) on the overall structure and then exposing a predetermined position of the silicide layer 407, the oxygen diffusion-protecting layer 431 is formed on the silicide layer 407, and includes at least one of TiN, TiAlN, TaN, or TaAlN. Next, the transition-metal oxide layer 432 is formed on the oxygen diffusion-protecting layer 431 to be electrically connected to the source region 404 through the oxygen diffusion-protecting layer 431 on the silicide layer 407. The oxygen diffusion-protecting layer 431 is provided to prevent the transition-metal oxide layer 432 from oxidizing the source region 404, which in turn may cause contact failure. The diffusion-protecting layer 431 also functions as the bottom electrode of the transition-metal oxide layer 432. The transition-metal oxide layer 432 contains at least an oxide among NiO, TiO₂, ZrO₂, HfO₂, Nb₂O₅, CoO₂, and CrO₂. The transition-metal oxide layer 432 is doped with at least an element such as Li, Cr, Ca, or La.

Next, the catalytic metal layer 434 is stacked on the transition-metal oxide layer 432 to help facilitate the growth of the carbon nanotube. The catalytic metal layer 434 may include at least one among metals such as Ni, Al, Co, Mo, Pt, Ca, Cr, Ti, Fe, Zr, W, Ir, Y, WSi, CoSi, NiSi, TiSi, TiW, and so on, include at least one oxide with the metal, or include a composite having a plurality of the above materials. The catalytic metal layer 434 functions as the top electrode of the transition-metal oxide layer 432.

Thus, the bottom electrode 431, the transition-metal oxide layer 432, and the catalytic metal layers 434 may constitute a data storage region 430.

Referring to FIG. 13B, the insulation layer 410 is deposited on the resultant structure of the substrate. Next, the contact holes 412 and 412′ are formed in the insulation layer 410 to expose the catalytic metal layer 434 and the metal silicide layer 407′. The carbon nanotubes 414 and 414′ may then be grown from the catalytic metal layer 434 and the metal silicide layer 407′ to respectively fill contact holes 412 and 412′. A technical method for growing the carbon nanotube is identical with or similar to that of FIG. 7C, and the catalytic metal remaining on the carbon nanotubes may be removed therefrom.

Subsequently, the metallic interconnection layers 440 and MO are formed on the carbon nanotubes 414 and 414′ and the insulation layer 410 to be electrically connected each with the carbon nanotubes 414 and 414′.

In these embodiments, the carbon nanotube is formed through the sequential processing steps of forming the contact hole in the insulation layer, and growing the carbon nanotube from the catalytic material of the lower conductive layer, the bottom electrode, or the transition-metal oxide layer. However, the present invention is not necessarily limited to these embodiments; rather, after filling the contact hole with the carbon nanotube, a supporting insulation layer may be used to fill a space between the contact hole and the carbon nanotube. The supporting insulation layer may be formed of USG or SOG to physically support the carbon nanotube.

Otherwise, after growing the carbon nanotubes from the catalytic material included in the lower conductive layer, the bottom electrode, or the transition-metal oxide layer, an insulation layer may be deposited on the overall structure including the carbon nanotube. This method is advantageous to self-alignment without an additional photolithography process for the contact holes.

With the two types of the processing steps, the insulation layer may cause the upward face of the carbon nanotube to be hardly exposed. In this case, the etch-back or CMP process may be carried out to expose the carbon nanotube, providing a structural pattern for electrical interconnections with conductive materials on the carbon nanotube.

In addition, while the embodiments are described as patterning the transition-metal oxide layer along with the top electrode, the present invention may be implemented to pattern only the top electrode without being limited thereto.

According to the features of the present invention described above, it is possible to construct the metal oxide resistive memory device in high integration density and to reduce power consumption by increasing resistance thereof.

Moreover, the metal oxide resistive memory device can be easily formed in a simple structure without an additional catalytic metal layer, because the catalytic material may be used from the transition-metal oxide layer or metal silicide employed in storing data.

While exemplary embodiments of the present invention have been illustrated and described in detail, it will be understood by those skilled in the art that various other modifications may be made, and equivalents may be substituted, without departing from the true scope of the present invention. Additionally, many modifications may be made to adapt a particular situation to the teachings of the present invention without departing from the central inventive concept described herein. Therefore, it is intended that the present invention not be limited to the particular embodiments disclosed, but that the present invention include all embodiments falling within the scope of the appended claims.

What is claimed is:

1. A memory device comprising:
a substrate;
a first insulation layer formed over the substrate;
a contact plug formed over the substrate and extending through the first insulation layer;
a lower conductive layer over the contact plug and at least a portion of the first insulation layer, the lower conductive layer including a transition-metal oxide layer;
a second insulation layer covering the lower conductive layer and the first insulation layer, the second insulation layer including a contact hole to expose at least a portion of the lower conductive layer;
a carbon nanotube formed in the contact hole over the lower conductive layer; and
an upper conductive layer over the insulation layer, the upper conductive layer overlying the carbon nanotube.

2. The memory device as set forth in claim 1, wherein the lower conductive layer includes a bottom electrode, the transition-metal oxide layer formed over the bottom electrode, and a top electrode formed over the transition-metal oxide layer, where the top electrode includes a catalytic agent for growth of the carbon nanotube.

3. The memory device as set forth in claim 2, wherein the bottom electrode includes a diffusion-protecting layer.

4. The memory device as set forth in claim 3, wherein the diffusion-protecting layer is formed over an impurity region in the substrate.

5. The memory device set forth in claim 1, further comprising a silicide layer formed in substrate, the silicide layer being in contact with the contact plug.

6. The memory device set forth in claim 5, wherein the contact plug includes a second carbon nanotube.

7. A method of fabricating a metal oxide resistive memory device, comprising:
forming a first insulation layer on a substrate, the first insulation layer having a contact plug extending therethrough to contact the substrate;
forming a lower conductive layer including a transition-metal oxide layer over the contact plug and a portion of the first insulation layer;
growing a carbon nanotube over the lower conductive layer and forming a second insulation layer that surrounds the carbon nanotube; and
forming an upper conductive layer overlying the carbon nanotube and over the second insulation layer, where the upper conductive layer is electrically connected with the carbon nanotube.

8. The method as set forth in claim 7, wherein forming the carbon nanotube and the second insulation layer includes:
forming the second insulation layer over the lower conductive layer;
forming a contact hole to expose at least a portion of the lower conductive layer; and
growing the carbon nanotube from the transition-metal oxide layer in the contact hole over the lower conductive layer, where the transition-metal oxide layer is used as a catalytic agent.

9. The method as set forth in claim 8, further comprising forming a supporting insulation layer that fills a space between the contact hole and the carbon nanotube to surround the carbon nanotube.

10. The method as set forth in claim 7, wherein forming the carbon nanotube and the second insulation layer includes:
growing the carbon nanotube by using the transition-metal oxide layer as a catalytic agent along a vertical direction to the substrate; and
depositing the second insulation layer.

11. The method as set forth in claim 10, further comprising etching the second insulation layer to expose an upward face of the carbon nanotube.

12. The method as set forth in claim 7 further comprising forming a catalytic metal layer for the growth of the carbon nanotube over the transition-metal oxide layer.

13. The method as set forth in claim 7, wherein forming the lower conductive electrode includes forming a top and a bottom electrode respectively on and under the transition-metal oxide layer.

14. The method as set forth in claim 13, wherein forming the bottom electrode includes forming a diffusion-protecting layer.

15. The method as set forth in claim 7, further comprising forming a silicide layer in the substrate before forming the first insulation layer, the first insulation layer being formed so that the contact plug is in contact with the silicide layer.

16. The method as set forth in claim 15, wherein the contact plug in the insulation layer is a second carbon nanotube formed by growing the second carbon nanotube over the silicide layer to extend through the first insulation layer.
